(19) United States
(12) Patent Application Publication
(10) Pub. No.: US 2023/0100906 A1
(43) Pub. Date: Mar. 30, 2023

(54) Actuating an MR Device with Saturation

(71) Applicant: Siemens Healthcare GmbH, Erlangen (DE)

(72) Inventors: David Grodzki, Erlangen (DE); Dieter Ritter, Fürth (DE)

(73) Assignee: Siemens Healthcare GmbH, Erlangen (DE)

(21) Appl. No.: 17/957,034

(22) Filed: Sep. 30, 2022

(30) Foreign Application Priority Data
Sep. 30, 2021 (DE) 102021211002.9

(51) Int. Cl. G01R 33/48; G01R 33/483; G01R 33/54

(52) U.S. Cl. CPC G01R 33/4828; G01R 33/4838; G01R 33/543

(57) ABSTRACT

In a method for actuating a magnetic resonance system including a radio-frequency unit configured to generate a radio-frequency (RF) pulse for saturating nuclear spins in an examination area of an examination object, a BO card of the magnetic resonance system is loaded, frequency information of nuclear spins to be saturated in the examination area is loaded, a subarea of the examination area in which nuclear spins are to be saturated is determined, at least one RF saturation pulse for saturating the nuclear spins to be saturated in the determined subarea is determined based on the BO card and the frequency information, and the RF saturation pulse is output via the radio-frequency unit of the magnetic resonance system.

### CROSS REFERENCE TO RELATED APPLICATIONS

This patent application claims priority to German Patent Application No. 102021211002.9, filed Sep. 30, 2021, which is incorporated herein by reference in its entirety.

### BACKGROUND

### Field

The disclosure relates to a method for actuating a magnetic resonance device by outputting a saturation pulse.

### Related Art

Magnetic resonance (MR) technology is a known technology with which images can be generated from the inside of an examination object. In simple terms, for this purpose the examination object is positioned in a magnetic resonance device in a comparatively strong static, homogeneous main magnetic field, also referred to as B0 field, with field strengths of 0.2 tesla to 7 tesla and more, so that the nuclear spins thereof are oriented along the basic magnetic field. In order to trigger nuclear spin resonances which can be measured as signals, radio-frequency excitation pulses (RF pulses) are radiated into the examination object, the triggered nuclear spin resonances are measured as so-called k-space data and MR images are reconstructed on the basis thereof or spectroscopy data are determined. RF pulses typically correspond to an alternating magnetic field. For the location coding of the measurement data, fast-switched magnetic gradient fields, referred to as gradients for short, are superimposed on the basic magnetic field. A scheme used, which describes a time sequence of RF pulses to be irradiated and gradients to be switched, is referred to as a pulse sequence (scheme), or also abbreviated as a sequence. The recorded measurement data is digitized and stored as complex numerical values in a k-space matrix. An associated MR image can be reconstructed from the k-space matrix occupied by values, for example by means of a multidimensional Fourier transform.

The intensity of MR signals is dependent on the environment of the nuclear spins, in particular of the molecules which comprise the nuclear spins. As a result, a contrast is produced in the reconstructed image data, fat, for example, having a different signal intensity than water, which predominates, for example, in muscle tissue. The suppression of signals emanating from a specific tissue, also referred to as saturation, is a customary technology in magnetic resonance imaging. The saturation can take place spectrally, wherein the chemical shift between nuclear spins in different tissues is utilized: nuclear spins have a different resonance frequency, that is to say Larmor frequency with respect to the strength of the main magnetic field, depending on the surrounding tissue. First, an RF saturation pulse, that is to say an RF pulse with a low frequency bandwidth is played out for resonant excitation of saturated nuclear spins bound in a defined tissue, which nuclear spins dephase in the defined tissue before RF pulses and gradient fields are played out for generating desired MR signals to be measured. The RF saturation pulses have such a frequency band that nuclear spins bound in other tissue are largely not excited. Only nuclear spins which lie outside the frequency band of the RF saturation pulses then contribute to the MR signals for the imaging. The spectral saturation depends in particular on the homogeneity of the main magnetic field and on the tissue to be suppressed, that is to say the tissue to be saturated.

Saturation of certain nuclear spins, for example nuclear spins bound in a certain tissue, generally leads to a decrease in the overall measurable signal by suppressing the signals emitted by these nuclear spins and thus to an overall decrease in the signal-to-noise ratio (SNR). For example, fat saturation generally leads to a decrease in the overall measurable signal due to the suppression of signals from protons bound in fat, and the SNR of the MR measurement is thus lower overall than in a comparable measurement without saturation. In general, this also worsens the image impression which an MR image reconstructed from measurement data recorded using saturation has. It is known to try to equalize the SNR again by means of averaging methods in which a higher number of measurements are carried out and averaged. However, this is accompanied by an overall longer measurement time due to the increased number of measurements.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a flowchart of a method according to an exemplary embodiment of the present disclosure.

FIG. 2 is a view of a test image of an examination area of an examination object according to an exemplary embodiment of the present disclosure.

FIG. 3 shows a radio-frequency unit of a magnetic resonance system according to an exemplary embodiment of the present disclosure.

FIG. 4 shows a magnetic resonance system according to an exemplary embodiment of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to improve imaging in a magnetic resonance tomograph (scanner) using RF saturation pulses, in particular with improved SNR.

The object is achieved by a method for actuating a magnetic resonance system comprising a radio-frequency unit configured to generate a radio-frequency pulse (RF pulse) for saturation of nuclear spins in an examination area of an examination object according to exemplary embodiments, a magnetic resonance system according to exemplary embodiments, and a computer program product computer readable medium according to exemplary embodiments.

A method according to the disclosure for actuating a magnetic resonance system comprising a radio-frequency unit configured to generate a radio-frequency pulse for saturating nuclear spins in an examination area of an examination object may include:
Loading a B0 card (B0) of the magnetic resonance system (1),
Loading frequency information (F) of nuclear spins to be saturated in the examination area,
Determining a subarea of the examination area in which nuclear spins are to be saturated,
Determining at least one RF saturation pulse (RF-S) for saturating the nuclear spins to be saturated in the specific subarea based on the B0 card (B0) and the frequency information (F),
Outputting the RF saturation pulse (RF-S) via the radio-frequency unit (7) of the magnetic resonance system (1).

Image data are typically to be generated from an area of the examination object, the examination area, as part of a magnetic resonance examination. The examination object is typically a patient. The examination area typically comprises a section of the examination object.

The frequency information permits a determination of a Larmor frequency of the nuclear spins to be saturated in their chemical compound (in their tissue) at which the nuclear spins are resonantly excited. The Larmor frequency results from the gyromagnetic ratio of a nuclear spin and the strength of the magnetic field surrounding the nuclear spin. The magnetic field surrounding the nuclear spin results predominantly from the main magnetic field which, however, is modulated on the basis of the chemical environment of the nuclear spin, in particular of the tissue surrounding the nuclear spin. The modulation is quantified on the basis of the chemical shift, which is, for example, approximately 3.4 ppm between fat and water. The frequency information can comprise, for example, a gyromagnetic ratio applicable to nuclear spins to be saturated, optionally with an associated chemical shift. The main magnetic field itself can have local variations. The main magnetic field can also be referred to as a B0 field. The loaded B0 card shows the strength of the main magnetic field in spatial resolution.

A B0 card for a magnetic resonance system can be stored on a storage medium which is accessed as part of the loading process. The B0 card contains at least information about a static spatial change of the main magnetic field. However, it can also comprise information about dynamic changes such as arise, for example, due to eddy currents caused by the switching of gradient fields. Furthermore, the B0 card can include information about changes of the main magnetic field specific to the examination object. The measurement of a static B0 card can be performed, for example, by means of a field camera or by means of an MR measurement or the B0 card can have been determined by simulation. The B0 card may also be referred to as a B0 map.

Frequency information for various nuclear spins to be saturated can be stored on a storage medium which is accessed as part of the loading process.

In general, RF pulses have a frequency bandwidth around a fundamental frequency and are accordingly emitted in a frequency band defined by the fundamental frequency and the frequency bandwidth. The fundamental frequency corresponds to the frequency of the RF pulse, that is to say the carrier frequency. An RF pulse causes a resonant excitation of a substance, provided that the Larmor frequency of a nuclear spin encompassed by the substance, that is to say the resonance frequency of the substance, corresponds to the frequency of the radio-frequency pulse, in particular at the position of the nuclear spin. An RF pulse can cause an excitation of a substance, provided that the Larmor frequency of a nuclear spin encompassed by the substance is encompassed by the frequency band of the RF pulse.

A substance can be, for example a molecule, a composition of different molecules, and/or a tissue. A substance can also be a further structure, which is not explicitly mentioned here, and is not limited to the examples mentioned.

An RF pulse designed for spectrally selective excitation of nuclear spins of a tissue typically has a frequency band which comprises the resonance frequency of these nuclear spins.

An RF saturation pulse designed for spectrally selective excitation of nuclear spins to be saturated on the basis of a loaded B0 card of a magnetic resonance system to be used is typically determined in such a way that a local influence on the basis of local changes in the main magnetic field on the resonance frequency of the nuclear spins to be saturated, in particular a local modulation of the resonance frequency, is determined and/or taken into account on the basis of the B0 card.

According to the disclosure, the volume in which the RF saturation pulse is to saturate nuclear spins is limited to a specific subarea of the examination area. As a result of the fact that the saturation effect of the RF saturation pulse no longer acts on the entire examination area, more signals are obtained in the case of an MR measurement using such an RF saturation pulse, which improves the SNR.

A magnetic resonance system according to the disclosure comprises a magnet unit, a gradient unit, a radio-frequency unit and a controller configured to carry out a method according to the disclosure with a saturation pulse determination unit.

A computer program according to the disclosure implements a method according to the disclosure on a controller when it is executed on the controller.

The computer program can also be in the form of a computer program product which can be loaded directly into a memory of a controller, with program code means for carrying out a method according to the disclosure when the computer program product is executed in the computing unit of the computer system. The computer program product may be embodied on a memory.

An electronically readable data carrier (e.g. memory) according to the disclosure comprises electronically readable control information stored thereon, which comprises at least one computer program according to the disclosure and is designed in such a way that it carries out a method according to the disclosure when the data carrier is used in a controller of a magnetic resonance system.

The advantages and embodiments specified in relation to the method also apply analogously to the magnetic resonance system, the computer program product and the electronically readable data carrier.

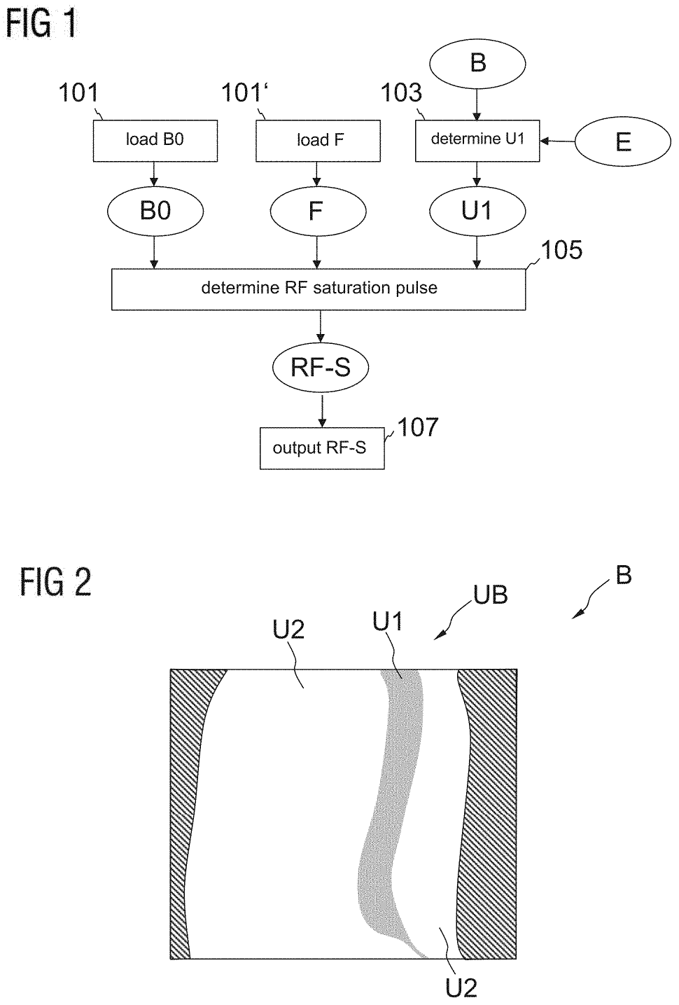

FIG. 1 is a diagrammatic view of a flow chart of a method according to the disclosure for actuating a magnetic resonance system comprising a radio-frequency unit 7 configured to generate a radio-frequency pulse for saturating nuclear spins in an examination area of an examination object.

A B0 card B0 of the magnetic resonance system is loaded (block 101). The B0 card can be loaded from a memory or can be determined and loaded in a known manner. The B0 card shows at least static changes in a spatial distribution of the main magnetic field but can also include dynamic changes and/or changes specific to the examination object.

Frequency information F of nuclear spins to be saturated in the examination area is loaded (block 101′). Frequency information for nuclear spins to be saturated, for example, nuclear spins bound in different tissues, can likewise already be present in stored form and be loaded from a memory in which, for example, a list of possible nuclear spins to be saturated with associated frequency information F is stored. The frequency information F can be measured or be based on literature values.

A subarea U1 is determined in which nuclear spins are to be saturated with the RF saturation pulse (block 103). In this case, the subarea U1 can be automatically determined, for example on the basis of a test image B of the examination area in which, for example, a desired anatomy was determined as subarea U1 by a segmentation method. A test image B can in particular be a calibration measurement or a pre-scan, for example, the resolution of which is reduced compared to diagnostic MR images. However, it is also possible to use a diagnostic MR image which shows the examination area as test image B. The subarea U1 can be determined by a user input E. In this case, the user input E can specify, for example, a desired anatomy in which nuclear spins are to be saturated, for example, the spinal column. The user input can also directly specify the subarea U1.

Thus, the subarea U1 can be determined in such a way that it covers an anatomical target area of the examination object U, for example a spinal column, in the examination area UB.

FIG. 2 is a roughly diagrammatic view of a test image B of an examination area UB of an examination object. The examination area UB is depicted in the test image B. The boundary areas of the test image B characterized by a pattern of diagonal lines lie outside the examination area UB.

A subarea U1 of the examination area UB characterized by a dot pattern was determined in which nuclear spins are to be saturated, so that signals of these nuclear spins are suppressed. Areas U2 of the examination area UB which do not coincide with the subarea U1 are shown in FIG. 2 as white areas. In these areas U2, nuclear spins of the same type as those which are saturated by the RF saturation pulse in the subarea U1 are to be at least incompletely saturated.

At least one RF saturation pulse RF-S for saturating the nuclear spins to be saturated is determined based on the B0 card B0 and the frequency information F (block 105). In this case, the RF saturation pulse RF-S is determined in such a way that, when it is irradiated into an examination object in the magnetic resonance system, it compensates for static deviations in the main magnetic field in the subarea U1. A determined RF saturation pulse RF-S causes an excitation of the nuclear spins to be saturated in a subarea U1 of an examination area UB located in the measurement volume of the magnetic resonance system, so that they are completely saturated. In this case, the determined RF saturation pulse RF-S is simultaneously determined in such a way that, in other areas U2 of the examination area UB which do not coincide with the subarea U1, it at least does not cause any complete excitation of nuclear spins of the same type, for example, nuclear spins bound in a same tissue, such as the nuclear spins to be saturated in the subarea U1. Thus, by means of the determined RF saturation pulse RF-S, complete saturation is achieved only in a subarea U1 in which suppression of nuclear spins of certain substances is required, for example for diagnostic capability, with little or no saturation of similar nuclear spins (of the same substance or substances) not being suppressed outside the subarea U1. For example, good fat saturation in the area of the vertebral bodies and the spinal canal of a spinal column is important for diagnostic capability, while external fat on the back near the spinal column is usually not of diagnostic interest and the saturation state of such fatty tissue is therefore unimportant.

In this case, when determining the RF saturation pulse RF-S, it can be specified as a boundary condition that the RF saturation pulse RF-S has no saturation effect on nuclear spins in areas U2 of the examination area which do not coincide with the subarea, in particular that there is no saturation at all in areas U2 by the RF saturation pulse RF-S. In this manner, the strongest possible signal is obtained from the areas U2 as no signals are suppressed by saturation. This leads to enhanced image quality.

It is also conceivable that, when determining the RF saturation pulse RF-S, an effect of the RF saturation pulse RF-S on areas U2 of the examination area UB which do not coincide with the subarea U1 is left open. In other words, the RF saturation pulse RF-S can be determined in such a way that it has undefined effect in areas U2 of the examination area UB which do not coincide with the subarea U1. In this case, it is unlikely that the RF saturation pulse causes a complete saturation of nuclear spins of the same type as the nuclear spins to be saturated in the subarea U1, so that in turn more signals can be measured from the areas U2. Furthermore, the determination of the RF saturation pulse RF-S can be carried out more quickly due to the lower boundary conditions (no boundary conditions for areas U2).

The determined RF saturation pulse RF-S is output via the radio-frequency unit 7 of the magnetic resonance system (block 107).

According to the disclosure, an RF saturation pulse is thus determined which is adapted temporally and spatially by different static and possibly dynamic magnetic field changes caused by different system-specific causes, and a complete saturation of signals of nuclear spins to be saturated is achieved only in a subarea U1 of the examination area UB. As a result, more signals overall are obtained as the saturation is only spatially selective, and thus signals are also only suppressed spatially selectively. Thus, an SNR is increased, resulting in improved image quality, and thereby enabling the avoidance of further MR measurements for averaging methods to increase the SNR.

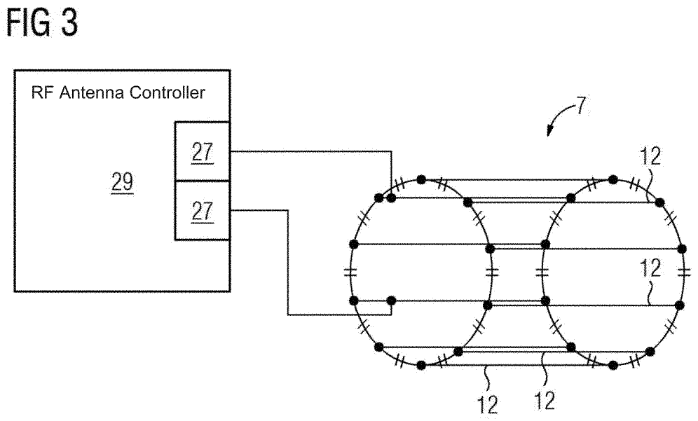

FIG. 3 shows a radio-frequency unit 7 in a diagrammatic view of a possible embodiment. The radio-frequency unit 7 comprises at least two transmitter elements 12 connected to a radio-frequency antenna unit and is connected to a radio-frequency antenna controller 29. According to this embodiment, the radio-frequency antenna controller 29 comprises a plurality of, preferably at least two, transmission channels 27. According to this embodiment, the transmission channels 27 feed a plurality of the transmitter elements 12 of the radio-frequency unit.

The radio-frequency antenna controller 29 may also comprise only one transmission channel 27. The radio-frequency unit 7 may comprise one transmitter element 12 or a plurality of transmitter elements 12, each of which is fed with exactly one independent transmission channel 27.

For the sake of clarity, only two independent transmission channels 27 are shown in FIG. 2, which are directly in signal connection with two of the transmitter elements 12. The further transmitter elements 12 are also fed by these by capacitive or inductive coupling. With such an actuation of the radio-frequency unit 7, it is usually possible to generate different elliptical polarizations with corresponding spatial amplitude distribution. With an increasing number of transmitter elements 12 fed independently by different transmission channels 27, the number of degrees of freedom increases in order to adjust the spatial component of the field distribution more finely.

The transmission channels 27 are supplied here, for example, by the radio-frequency antenna controller 29, which is, for example, part of a radio-frequency transceiver controller 7′, for example via a signal bus, with data of the RF saturation pulse to be transmitted and time coordination with the gradients or pulse sequence is controlled.

The radio-frequency antenna unit of the radio-frequency unit 7 formed from the transmitter elements 12 can be designed as a body coil of a magnetic resonance system. Instead of the body coil, for example, a local coil with an array of antenna coils is also conceivable. In contrast to the body coil, the effective areas of the individual antenna coils are significantly less coupled or completely disjoint in the case of antenna coils more remote from one another, so that spatial distribution is provided above all by the position of the antenna coil and less by interference with the signals of the other antenna coils.

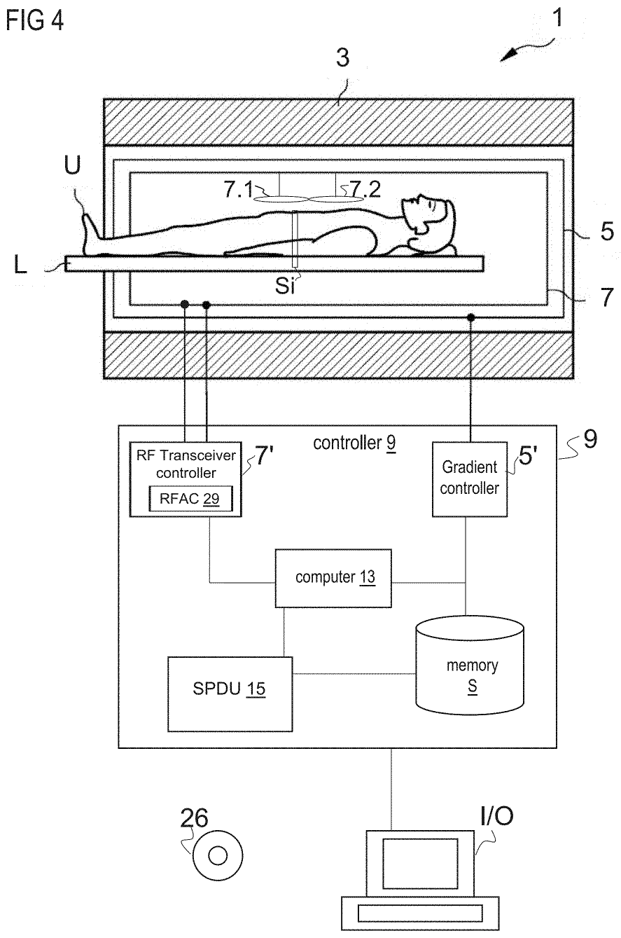

FIG. 4 is a diagrammatic view of a magnetic resonance system 1 according to an exemplary embodiment of the disclosure. The system 1 may include a magnet unit 3 for generating the basic magnetic field, a gradient unit 5 for generating the gradient fields, a radio-frequency (RF) unit 7 for irradiation and for receiving radio-frequency signals and a control facility (controller) 9 configured to carry out a method according to the disclosure. The magnet unit 3, the gradient unit 5, and the RF unit 7 may collectively be referred to as a MR scanner.

In FIG. 4, these partial units of the magnetic resonance system 1 are shown only roughly in a diagrammatic view. In particular, the radio-frequency unit 7 may consist of a plurality of subunits, for example of a plurality of coils like the diagrammatically shown coils 7.1 and 7.2 or more coils which can be designed either only for transmitting radio-frequency signals or only for receiving the triggered radio-frequency signals or for both. The radio-frequency unit 7 may be a radio-frequency unit 7 as it is described in relation to FIG. 2.

In order to examine an examination object U, for example a patient or also a phantom, it can be introduced on a bed L into the magnetic resonance system 1 in the measurement volume thereof. The layer or the Slab Si represents an exemplary target volume of the examination object from which echo signals are to be recorded and detected as measurement data.

With continued reference to FIG. 4, the controller 9 is configured to control the magnetic resonance system 1 and may particularly control the gradient unit 5 by means of a gradient controller 5′ and the radio-frequency unit 7 by means of a radio-frequency transceiver controller 7′. In this case, the radio-frequency unit 7 may comprise a plurality of channels on which signals can be transmitted or received.

The radio-frequency unit 7, together with its radio-frequency transceiver controller 7′, is responsible for the generation and the irradiation (transmission) of a radio-frequency alternating field for manipulating the spins in an area to be manipulated (for example, in layers S to be measured) of the examination object U. In this case, the center frequency of the radio-frequency alternating field, also referred to as B1 field, is generally set as far as possible in such a way that it is close to the resonance frequency of the spins to be manipulated. Deviations from the center frequency of the resonance frequency are referred to as off-resonance. In order to generate the B1 field, currents controlled by means of the radio-frequency transceiver controller 7′ are applied to the RF-coils in the radio-frequency unit 7.

Furthermore, the controller 9 may comprises a saturation pulse determination unit 15 which is connected to the radio-frequency transceiver controller 7′, and with which RF saturation pulses according to the disclosure are determined, which can be converted by the radio-frequency unit 7. The controller 9 as a whole may be configured to carry out a method according to the disclosure.

A computing unit (computer) 13 comprised by the controller 9 is configured to carry out all computing operations necessary for the necessary measurements and determinations. The intermediate results and results required or determined for this can be stored in a memory unit S of the controller 9. The units shown here are not necessarily to be understood as physically separate units but merely represent a subdivision into units of meaning which, however, can also be realized, for example, in fewer or even in only one single physical unit. In an exemplary embodiment, the controller 9 includes processing circuitry that is configured to perform one or more functions and/or operations of the controller 9. One or more of the components/units of the controller 9 may include processing circuitry that is configured to perform one or more corresponding functions and/or operations of the respective component(s).

Control commands can be sent to the magnetic resonance system and/or results from the controller 9 such as, for example, image data, can be displayed, for example by a user, via an input/output facility I/O of the magnetic resonance system 1. The input/output facility I/O may be an input/output interface, such as a general-purpose computer.

A method described herein can also be in the form of a computer program product which comprises a program and implements the described method on a controller 9 when it is executed on the controller 9. Likewise, there can also be an electronically readable data carrier (memory) 26 with electronically readable control information stored thereon which comprises at least one such computer program product just described and is designed in such a way that it carries out the method described when the data carrier 26 is used in a controller 9 of a magnetic resonance system 1.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” shall be understood to be circuit(y) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for actuating a magnetic resonance system including a radio-frequency unit configured to generate a radio-frequency (RF) pulse for saturating nuclear spins in an examination area of an examination object, the method comprising:
loading a B0 card of the magnetic resonance system,
loading frequency information of nuclear spins to be saturated in the examination area,
determining a subarea of the examination area in which nuclear spins are to be saturated,
determining at least one RF saturation pulse for saturating the nuclear spins to be saturated in the determined subarea based on the B0 card and the frequency information, and
outputting the RF saturation pulse via the radio-frequency unit of the magnetic resonance system.

2. The method as claimed in claim 1, wherein the subarea is determined automatically based on a test image of the examination area.

3. The method as claimed in claim 1, wherein the subarea is determined based on a user input.

4. The method as claimed in claim 1, wherein the RF saturation pulse has no saturation effect on nuclear spins in areas of the examination area which do not coincide with the subarea.

5. The method as claimed in claim 1, wherein the RF saturation pulse has a non-defined effect in areas of the examination area which do not coincide with the subarea.

6. The method as claimed in claim 1, wherein the subarea is configured such that it covers an anatomical target area of the examination object in the examination area.

7. The method as claimed in claim 1, wherein the radio-frequency unit has a plurality of transmission channels in signal connection with a plurality of transmitter elements of the radio-frequency unit, the RF saturation pulse having a plurality of components for the plurality of transmission channels.

8. The method as claimed in claim 1, wherein the B0 card includes a strength of a main magnetic field in spatial resolution.

9. A computer program product, embodied on a non-transitory computer-readable storage medium, that is loadable into a memory of a controller of the magnetic resonance system and includes a computer program, when the computer program is executed by the controller, controls the controller to perform the method as claimed in claim 1.

10. A non-transitory computer-readable storage medium having a computer program stored thereon, when executed by the processor, controls the processor to perform the method as claimed in claim 1.

11. A magnetic resonance (MR) system comprising:
a MR scanner having a radio-frequency unit; and
a controller that is configured to:
access a B0 card of the magnetic resonance system;
access frequency information of nuclear spins to be saturated in an examination area;
determine a subarea of the examination area in which nuclear spins are to be saturated;
determine at least one radio-frequency (RF) saturation pulse configured to saturate the nuclear spins to be saturated in the determined subarea based on the B0 card and the frequency information; and
control the MR scanner to output the RF saturation pulse via the radio-frequency unit.

12. The MR system as claimed in claim 11, wherein the MR scanner further comprises a magnet unit and a gradient unit.

13. The MR system as claimed in claim 11, wherein the controller comprises a radio-frequency (RF) transceiver controller and having an RF saturation pulse determination unit that is configured to determine the at least one RF saturation pulse.
